(19) United States
(12) Patent Application Publication
(10) Pub. No.: US 2022/0246515 A1
(43) Pub. Date: Aug. 4, 2022

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Yoshikazu KAZAMA, Nagano (JP)

(21) Appl. No.: 17/649,585

(22) Filed: Feb. 1, 2022

(30) Foreign Application Priority Data
Feb. 4, 2021 (JP) 2021-016875

(51) Int. Cl. H01L 23/498

(52) U.S. Cl. CPC H01L 23/49838; H01L 23/49866; H01L 24/16; H01L 23/49811; H01L 23/49827; H01L 23/49822

(57) ABSTRACT

An interconnect substrate includes an insulating layer, and an interconnect layer formed on a surface of the insulating layer, wherein the interconnect layer includes a plating layer, and an electrically conductive layer made of a sintered body comprised of an electrically conductive material.

### CROSS-REFERENCE TO RELATED APPLICATIONS

The present application is based upon and claims the benefit of priority from the prior Japanese Patent Application No. 2021-016875 filed on Feb. 4, 2021, with the Japanese Patent Office, the entire contents of which are incorporated herein by reference.

### FIELD

The disclosures herein relate to interconnect substrates and methods of making an interconnect substrate.

### BACKGROUND

Interconnect substrates have an interconnect layer formed on a surface thereof.

Large electric current may flow through the interconnect layer of an interconnect substrate, depending on the application. The thickness of an interconnect layer may be increased to allow the interconnect substrate to conduct large current. However, sufficient isolation may not be secured under some line pitch conditions.

The embodiments of the present invention provide an interconnect substrate and a method of making the interconnect substrate that can conduct an increased amount of current.

### RELATED-ART DOCUMENTS

### [Patent Document]

[Patent Document 1] U.S. patent Ser. No. 10/764,995

### SUMMARY

According to an aspect of the embodiment, an interconnect substrate includes an insulating layer, and an interconnect layer formed on a surface of the insulating layer, wherein the interconnect layer includes a plating layer, and an electrically conductive layer made of a sintered body comprised of an electrically conductive material.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A through 1C are cross-sectional views illustrating the method of forming an interconnect substrate according to a comparative example;

FIG. 2 is a cross-sectional view of interconnects when a tick plating layer is formed in the comparative example;

FIGS. 3A and 3B are cross-sectional views of an interconnect substrate according to a first embodiment;

FIG. 4 is a schematic cross-sectional view illustrating an example of a conductive layer;

FIGS. 5A through 5C are cross-sectional views illustrating the method of making the interconnect substrate according to the first embodiment;

FIGS. 6A through 6C are cross-sectional views illustrating the method of making the interconnect substrate according to the first embodiment;

FIGS. 7A through 7C are cross-sectional views illustrating the method of making the interconnect substrate according to the first embodiment;

FIGS. 8A and 8B are cross-sectional views illustrating the method of making the interconnect substrate according to the first embodiment;

FIGS. 9A through 9C are cross-sectional views illustrating the method of making the interconnect substrate according to the first embodiment;

FIG. 10 is a cross-sectional view illustrating the mode of use of the interconnect substrate according to the first embodiment;

FIG. 11 is a cross-sectional view of an interconnect substrate according to a second embodiment;

FIG. 12 is a cross-sectional view of an interconnect substrate according to a third embodiment; and

FIG. 13 is a cross-sectional view of an interconnect substrate according to a fourth embodiment.

### DESCRIPTION OF EMBODIMENTS

The inventor of the present application has conducted diligent study in order to satisfy the need for a current increase. For example, large current can be conducted by increasing the cross-sectional area of interconnects of an interconnect layer. An increase in the width of interconnects, however, results in an increase of the area of the interconnect substrate. In contrast, an increase in the thickness of interconnects can be achieved without increasing the area of the interconnect substrate. In consideration of this, the inventor of the present application studied the formation of a thick interconnect layer by use of the subtractive method.

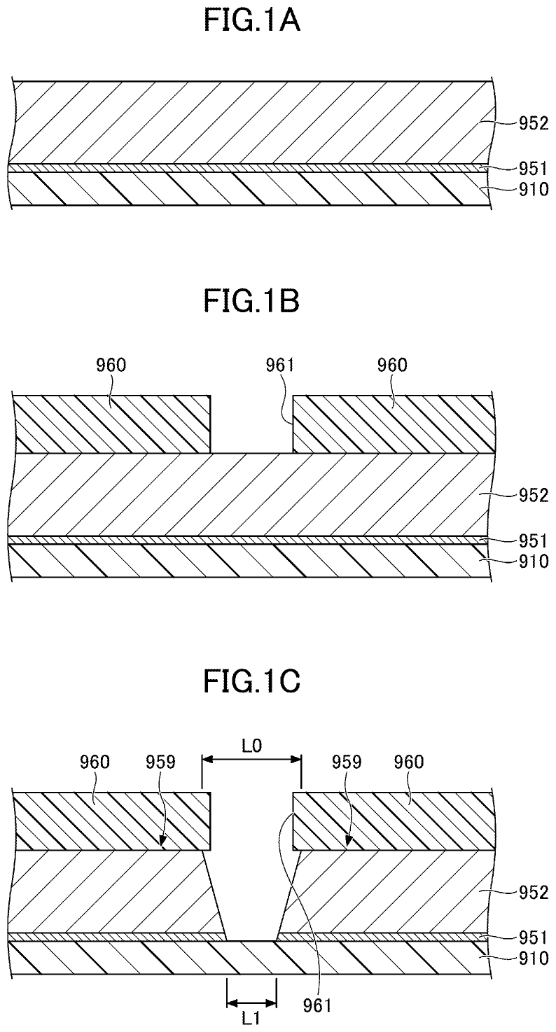

It was found that, in the case in which the subtractive method was used to form a thick interconnect layer, it was difficult to secure sufficient electrical isolation between adjacent interconnects. In the following, the mechanism of how it becomes difficult to maintain electrical isolation will be described. FIGS. 1A through 1C are cross-sectional views illustrating the method of forming an interconnect substrate according to a comparative example. In the present disclosures, a first side of an insulating layer may be referred to as an upper side, and a second side (i.e., the opposite side) thereof may be referred to as a lower side, for the sake of convenience. The surface (or face) of the insulating layer on the same side as the first side may be referred to as a first surface (or first face) or an upper surface (or upper face), and the surface (or face) of the insulating layer on the same side as the second side may be referred to as a second surface (or second face) or a lower surface (or lower face). It may be noted, however, that the interconnect substrate may be used in an upside-down position, or may be placed at any angle.

In the comparative example, an interconnect layer is formed on the first surface of an insulating layer. In forming the interconnect layer, as illustrated in FIG. 1A, a seed layer 951 is formed on the first surface of an insulating layer 910, and, then, a plating layer 952 is formed on the seed layer 951. The situation under consideration is such that the total thickness of the seed layer 951 and the plating layer 952 is 100 μm.

As illustrated in FIG. 1B, a resist layer 960 with an opening 961 corresponding to the space between adjacent interconnects is formed over the plating layer 952. Here, the opening 961 is formed such that the distance L0 between the upper ends of adjacent plating layers 952 (see FIG. 1C) is 200 μm after etching the plating layer 952 and the seed layer 951, which will be described later.

As illustrated in FIG. 1C, the resist layer 960 is used as a mask to etch the plating layer 952 and the seed layer 951 to form interconnects 959. When this is done, etching does not advance perpendicularly to the upper surface of the plating layer 952, but advances in a tapered fashion as illustrated in FIG. 1C. As a result, the bottom portion of the seed layer 951 that is in contact with the insulating layer 910 has the distance L1 between the lower ends of adjacent seed layers 951, which is less than the distance L0 between the upper ends of the adjacent plating layers 952. The distance L1 is 140 μm, for example. In certain applications of the interconnect substrate, the distance L1 greater than or equal to 140 μm can secure sufficient isolation. In such a case, the interconnects 959 obtained by this method are free from problems.

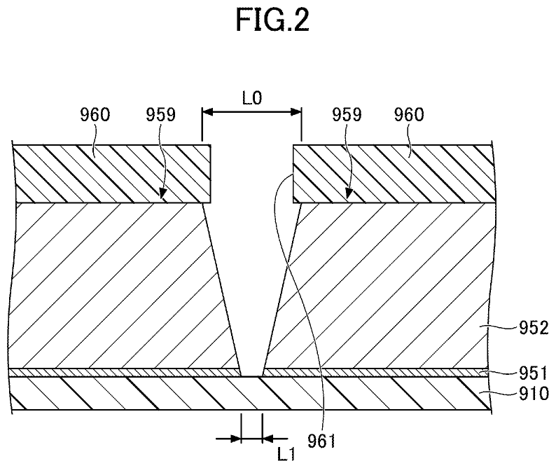

However, the thickness of the plating layer 952 may be increased in order to increase current, and, then, a distance L1 of 100 μm or more may not be obtained as described in the following. FIG. 2 is a cross-sectional view of interconnects when a tick plating layer is formed in a comparative example. here, the situation under consideration is such that the total thickness of the seed layer 951 and the plating layer 952 is 200 μm. In this case, use of the resist layer 960 as the mask that creates a distance L0 of 200 μm between the upper ends of adjacent plating layers 952 results in a further decrease in the distance L1 between the adjacent interconnects 959 at the bottom. The distance L1 is 40 μm, for example. The interconnects 959 obtained by this method are thus not sufficiently isolated.

In order to make the distance L1 greater than or equal to 140 μm while maintaining the total thickness of the seed layer 951 and the plating layer 952 at 200 μm, the distance L0 may be increased. However, this arrangement results in an increase of the area of the interconnect substrate as in the case of increasing the width of interconnects.

The inventor of the present application has made the following embodiments based on these newly-obtained insights.

In the following, the embodiment will be described with reference to the accompanying drawings. In the specification and drawings, elements having substantially the same functions or configurations are referred to by the same numerals, and a duplicate description thereof may be omitted.

### First Embodiment

### [Structure of Interconnect Substrate]

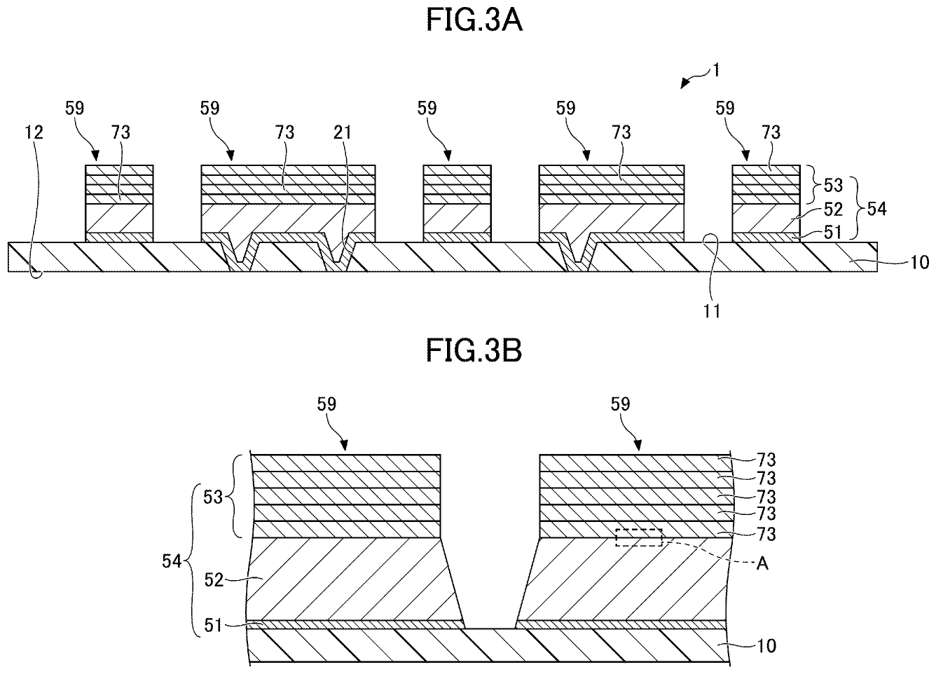

In the following, the structure of an interconnect substrate of a first embodiment will be described. FIGS. 3A and 3B are cross-sectional views of an interconnect substrate according to the first embodiment. FIG. 3B is an enlarged cross-sectional view of a portion illustrated in FIG. 3A.

In an interconnect substrate 1 according to the first embodiment, via holes 21 are formed in an insulating layer 10. The diameter of the via holes 21 is larger at the first end (i.e., the upper end) of the insulating layer 10 than at the second end (i.e., the bottom end), for example. The side surfaces of the via holes 21 are inclined surfaces forming a tapered profile. A plurality of via holes 21 may be formed. The insulating layer 10 is made of an insulating resin such as epoxy resin, polyimide resin, or the like.

An interconnect layer 54 containing a plurality of interconnects 59 is formed in the via hole 21 and on a first surface 11 of the insulating layer 10. The interconnect layer 54 includes a seed layer 51, a plating layer 52 formed on the seed layer 51, and a conductive layer 53 formed on the plating layer 52. The seed layer 51 is a Cu layer, for example. The plating layer 52 is a Cu plating layer, for example. The conductive layer 53 is made of a sintered body such as a copper sintered body, for example. The seed layer 51 is exposed at the via holes 21 on the second surface 12 of the insulating layer 10. The conductive layer 53 may include a plurality of sintered layers 73 stacked on one another, or may have a single sintered layer 73. The interconnect layer 54 may also be plated on the surface thereof.

The width of the conductive layer 53 of each interconnect may be the same as the width of the upper surface of the plating layer 52 (i.e., the surface in contact with the conductive layer 53). Because the conductive layer 53 is formed by sintering, the width of the conductive layer 53 may be smaller than the width of the upper surface of the plating layer 52, so that a portion of the upper surface of the plating layer 52 may be exposed. The width of conductive layer 53 of each interconnect is smaller than the width of the lower surface of the plating layer 52 (i.e., the surface in contact with the seed layer 51). The conductive layer 53, when comprised of a plurality of sintered layers 73, may be such that the side surfaces of the sintered layers 73 may be flush with each other as illustrated in FIG. 3, or may recede or protrude from one another.

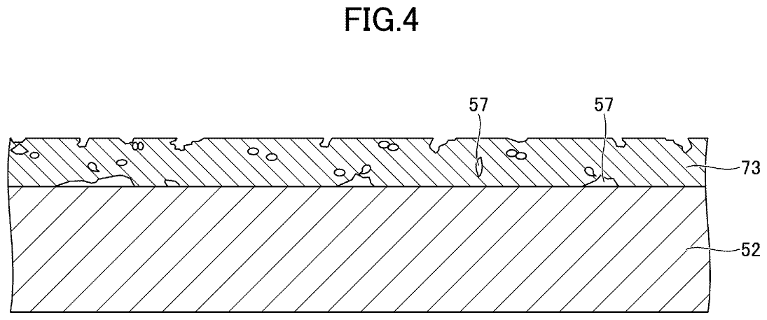

FIG. 4 is a schematic cross-sectional view illustrating an example of a portion of the conductive layer 53 which portion is indicated by a dashed enclosing line A in FIG. 3B. There may be pores in the sintered body constituting the conductive layer 53. That is, there may be spaces 57 inside the conductive layer 53, as illustrated in FIG. 4. There are no pores (spaces) in the plating layer 52. The surface of the conductive layer 53 may have recesses and bulges. Under the electron microscopic inspection of a plane parallel to the thickness direction of the plating layer 52 and the conductive layer 53, the conductive layer 53 may be coarser than the plating layer 52. The electrical resistivity of the plating layer 52 may be less than the electrical resistivity of the conductive layer 53.

### [Method of Making Interconnect Substrate]

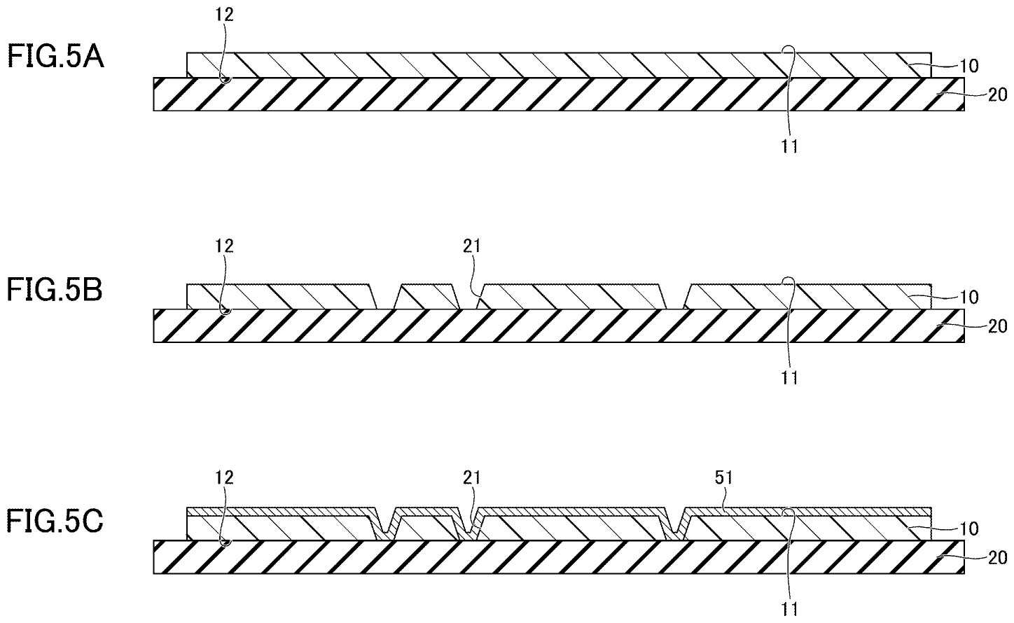

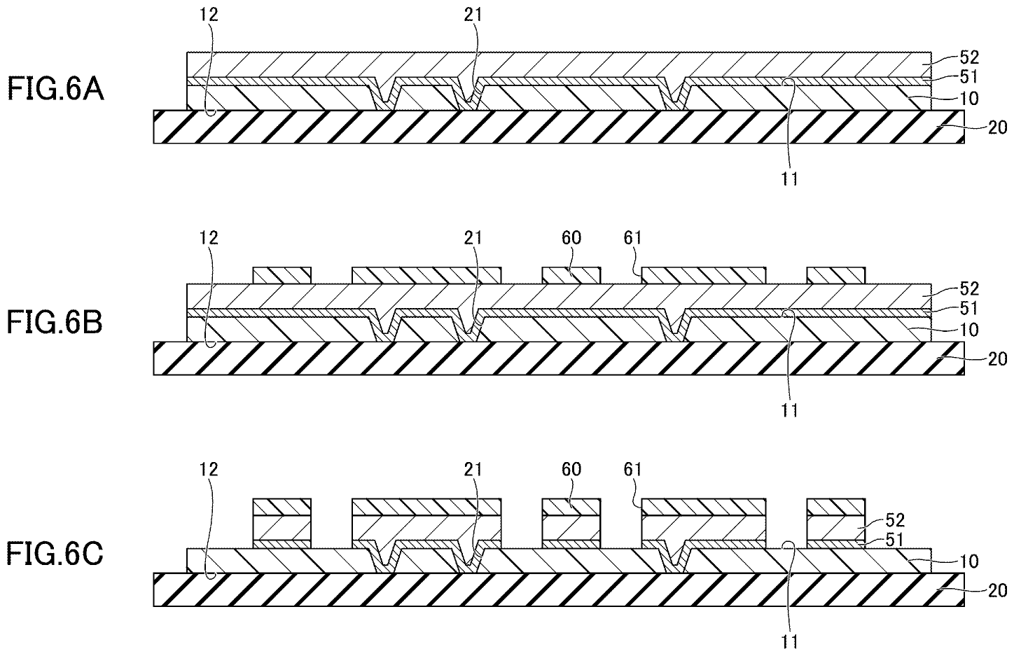

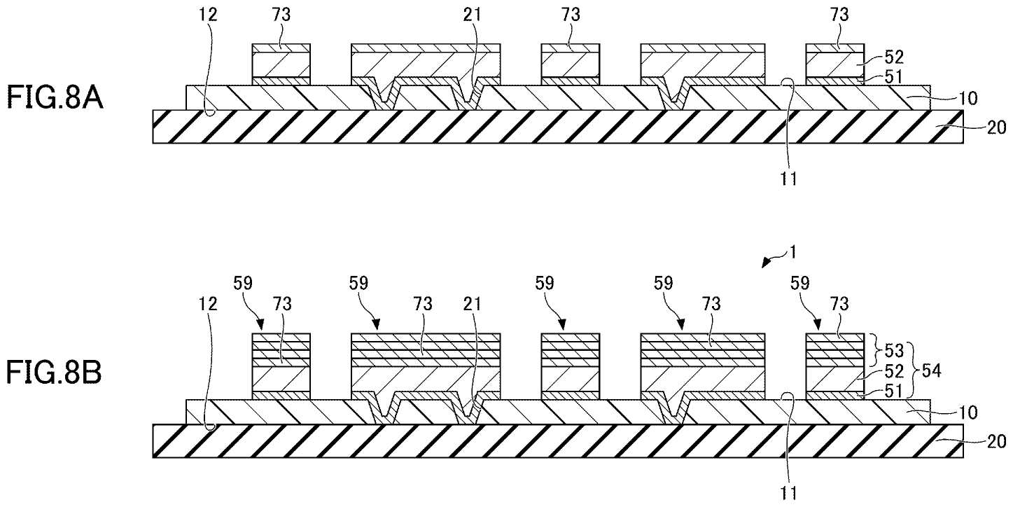

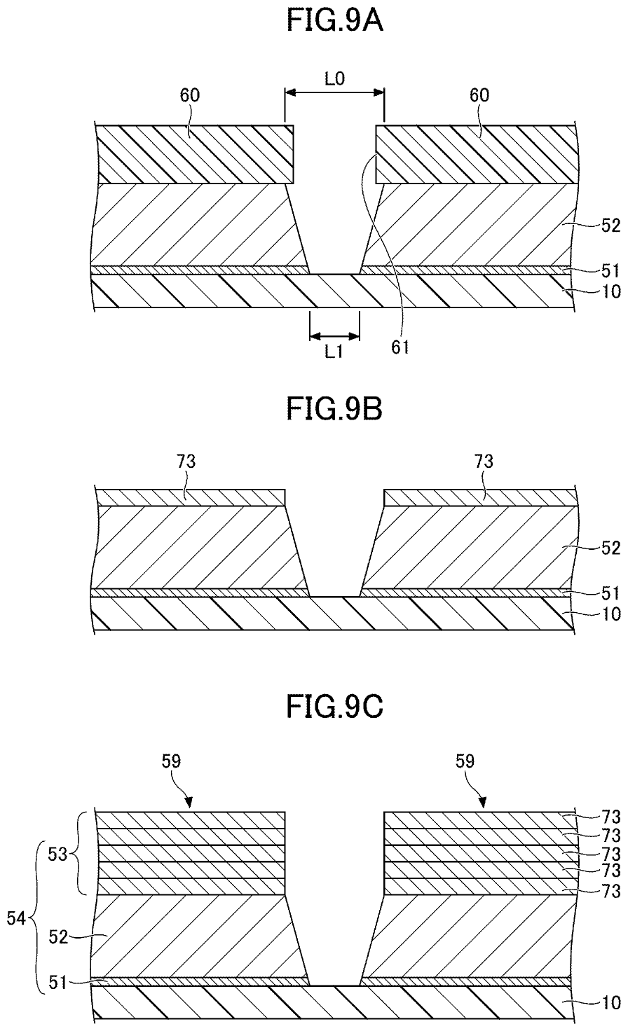

In the following, a method of making the interconnect substrate 1 of the first embodiment will be described. FIGS. 5A-5C through FIGS. 9A-9C are cross-sectional views illustrating a method of making the interconnect substrate 1 according to the first embodiment. FIGS. 9A, 9B, and 9C are enlarged cross-sectional views of portions illustrated in FIG. 6C, FIG. 8A, and FIG. 8B, respectively.

As illustrated in FIG. 5A, a support substrate 20 is put in place, and, then, an insulating layer 10 is formed on the support substrate 20. An insulating resin layer such as, for example, an epoxy resin layer or a polyimide resin layer may be used as the insulating layer 10. The insulating layer 10 has a surface 12 in contact with the support substrate 20 and an opposite surface 11.

As illustrated in FIG. 5B, via holes 21 are formed in the insulating layer 10. The via holes 21 may be formed by directing laser light to the insulating layer 10 from the upper side thereof, for example. The via holes 21 may alternatively be formed by photolithography.

As illustrated in FIG. 5C, a seed layer 51 is formed on the first surface 11 of the insulating layer 10, on the side surfaces of the via holes 21, and on the surfaces, exposed in the via holes 21, of the support substrate 20. The seed layer 51 may be formed by sputtering, for example.

Subsequently, as illustrated in FIG. 6A, a plating layer 52 is formed on the seed layer 51 by electrolytic copper plating utilizing the seed layer as a feeding path. The thickness of the plating layer 52 is approximately 50 μm to 100 μm, for example.

As illustrated in FIG. 6B, a resist layer 60 with openings 61 corresponding to the spaces between the adjacent interconnects 59 is formed over the plating layer 52. The resist layer 60 may be a dry film resist or the like, for example, and the openings 61 are formed in the resist layer 60 by exposure and development.

As illustrated in FIG. 6C, the resist layer 60 is used as a mask to etch the plating layer 52 and the seed layer 51. When this is done, etching does not advance perpendicularly to the upper surface of the plating layer 52, but advances in a tapered fashion as illustrated in FIG. 9A. As a result, the bottom portion of the seed layer 51 that is in contact with the insulating layer 10 has the distance L1 between the lower ends of adjacent seed layers 51, which is less than the distance L0 between the upper ends of the adjacent plating layers 52. The present embodiment is configured in view of the characteristics of etching as noted above such that the distance L0 between the upper ends of adjacent plating layers 52 is set to ensure sufficient isolation between adjacent seed layers 51. The plating layer 52 prior to etching is an example of the first layer.

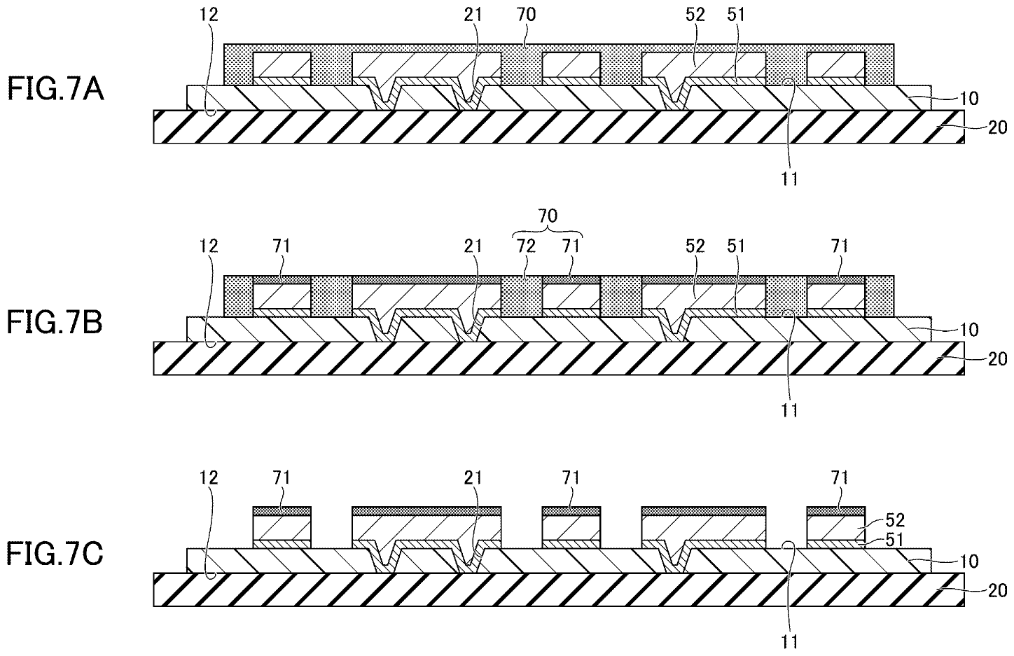

Subsequently, as illustrated in FIG. 7A, the resist layer 60 is removed, and a photosensitive conductive material 70 is provided to cover the plating layer 52 and the seed layer 51. The photosensitive conductive material 70 includes a photosensitive organic material as a base and electrically conductive particles made of gold, silver, silver palladium alloy, copper, platinum, tungsten, or the like, for example. Although this example is directed to the case in which a negative photosensitive organic material is used as the photosensitive organic material, a positive photosensitive organic material may alternatively be used. The photosensitive conductive material 70 may be put in place by applying the material. Alternatively, a photosensitive conductive material film may be used. The thickness of the photosensitive conductive material 70 may approximately be 5 μm to 15 μm over the plating layer 52, for example. It is preferable to provide the photosensitive conductive material 70 such that an alignment mark (not shown) formed in advance on the insulating layer 10 can be identified. For example, the photosensitive conductive material 70 is preferably provided without covering an alignment mark (not shown).

As illustrated in FIG. 7B, the portions of the photosensitive conductive material 70 situated over the plating layer 52 are exposed to light to form exposed portions 71. The remaining portions of the photosensitive conductive material 70 are unexposed portions 72. An alignment mark can be utilized for alignment during the exposure of the photosensitive conductive material 70.

The photosensitive conductive material 70 is then developed. As a result, as illustrated in FIG. 7C, the unexposed portions 72 are dissolved and removed by the developing liquid, and the exposed portions 71 are left to remain on the plating layer 52.

Thereafter, as illustrated in FIG. 8A and FIG. 9B, the exposed portions 71 are heated to turn into a sintered layer 73 made of a sintered body of conductive particles. The thickness of the sintered layer 73 is approximately the same as the thickness of the portions of the photosensitive conductive material 70 situated over the plating layer 52, and is approximately 5 μm to 15 μm.

Subsequently, the application of the photosensitive conductive material 70 (FIG. 7A) to the heating of the exposed portions 71 (FIG. 8A) are repeated one or more times to obtain the conductive layer 53 that includes a plurality of sintered layers 73, as illustrated in FIGS. 8B and 9C. This results in an interconnect layer 54 including the seed layer 51, the plating layer 52, and the conductive layer 53. The repeating process noted above may be omitted so as to form a conductive layer 53 having a single sintered layer 73. The interconnect layer 54 may be subjected to nickel plating, palladium plating, and gold plating in this order. Other plating may alternatively be applied to the interconnect layer 54. The interconnect layer 54 includes a plurality of interconnects 59. In this manner, the interconnect substrate 1 is completed.

The interconnect substrate 1 is then detached from the support substrate 20.

In the present embodiment, the conductive layer 53 is formed on the plating layer 52 after etching. In order to form this conductive layer 53, the photosensitive conductive material 70 is exposed, developed, and heated to form the sintered layer 73, which is then repeated one or more times as needed. A thick plating layer 52 does not need to be formed, and, yet, the interconnect layer 54 is obtained that has a sufficient thickness for conducting large current. In other words, the present embodiment enables the conduction of an increased amount of current while avoiding an area increase and while securing sufficient isolation.

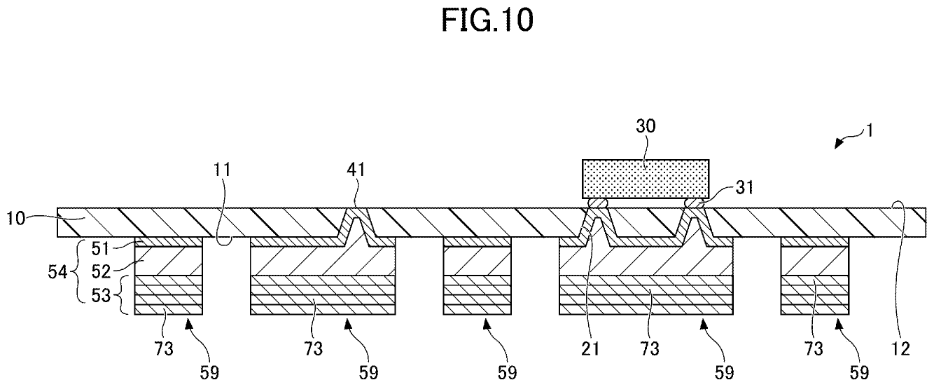

In the following, the mode of use of the interconnect substrate 1 according to the first embodiment will be described. FIG. 10 is a cross-sectional view illustrating the mode of use of the interconnect substrate 1 according to the first embodiment.

As illustrated in FIG. 10, the interconnect substrate 1 is used in the configuration in which a semiconductor device 30 is mounted on the second surface 12 thereof. In this configuration, the seed layer 51 exposed at the second surface 12 of the interconnect substrate 1 functions as connections 41. The semiconductor device 30 may be, for example, an electronic component serving as an active device (e.g., a central processing unit (CPU) or a silicon chip such as a memory), a transistor such as a MOS-type field effect transistor (FET), or a resistor. A plurality of terminals 31 are provided on the first surface of the semiconductor device 30. The terminals 31 are arranged at the positions corresponding to the positions of the via holes 21, and are connected to some of the connections 41. The connections 41 may be directly connected to the electrodes of the semiconductor element 30 without the terminals 31. The remaining connections 41 may be connected to other semiconductor devices or to another interconnect substrate. A protective insulating layer (e.g., a solder resist layer) may also be formed on the first surface 11 of the insulating layer 10, with openings that expose some portions of the surface of the interconnect layer 54 (i.e., portions of the surface of the conductive layer 53). In the case in which the surface of the conductive layer 53 has surface irregularities, such surface irregularities increase a contact area, thereby improving an adhesion with the protective insulating layer. In addition, the irregularities of the surface of the conductive layer also increase a contact area with respect to a connection such as a solder, thereby improving the adhesion.

### Second Embodiment

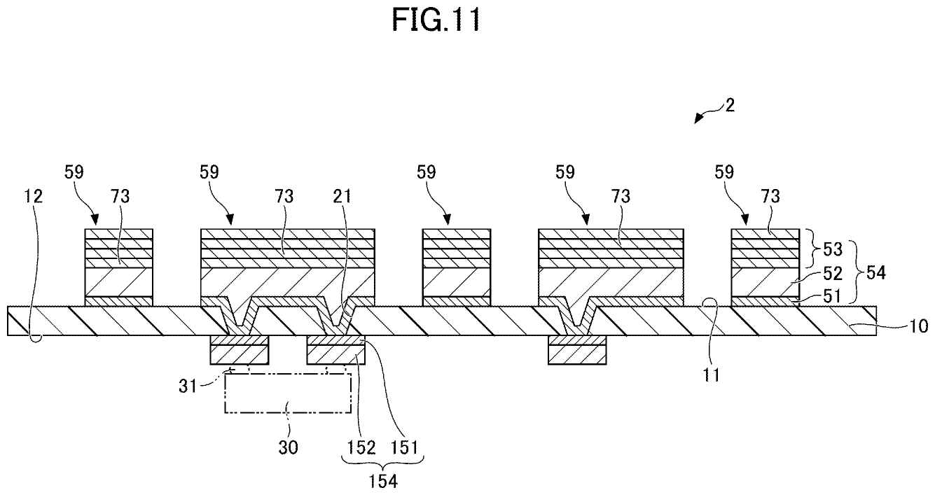

In the following, a second embodiment will be described. FIG. 11 is a cross-sectional view of an interconnect substrate according to the second embodiment.

As illustrated in FIG. 11, an interconnect substrate 2 of the second embodiment has an interconnect layer 154, added to the interconnect substrate 1, on the surface of the seed layer 51 exposed in the via holes 21. The interconnect layer 154 includes a seed layer 151 in contact with the seed layer 51, and includes a plating layer 152 formed on the second side of the seed layer 151.

The remainder of the configuration of the second embodiment is substantially the same as the configuration of the first embodiment.

The second embodiment brings about substantially the same advantageous effects as those of the first embodiment.

In the second embodiment, the interconnect layer 154 is used as a connection to one or more semiconductor devices and/or one or more other interconnect substrates, for example.

In order to make the interconnect substrate according to the second embodiment, the interconnect layer 154 may be formed by a subtractive method after the interconnect substrate 1 is made, for example.

The interconnect layer 154 may further include a conductive layer similar to the conductive layer 53 on the plating layer 152.

### Third Embodiment

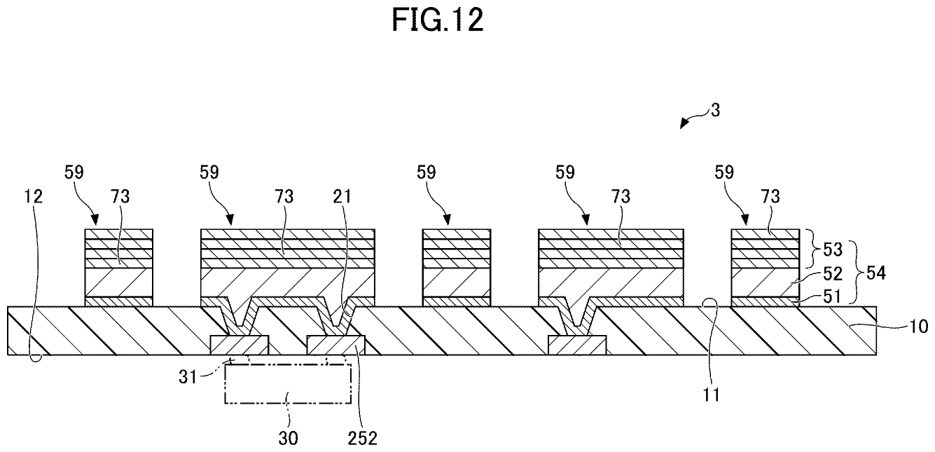

In the following, a third embodiment will be described. FIG. 12 is a cross-sectional view of an interconnect substrate according to the third embodiment.

As illustrated in FIG. 12, an interconnect substrate 3 according to the third embodiment has a plating layer 252 embedded in the insulating layer 10 and exposed at the second surface 12. The via holes 21 extend from the first surface 11 of the insulating layer 10 to the first surface of the plating layer 252, and the seed layer 51 is in contact with the first surface of the plating layer 252. The surface of the plating layer 252 (i.e., the surface connected to the semiconductor device 30) may be flush with the second surface 12 of the insulating layer 10.

The remaining configurations are substantially the same as the configurations of the first embodiment.

The third embodiment brings about substantially the same advantageous effects as those of the first embodiment.

In the third embodiment, the plating layer 252 is used as a connection to one or more semiconductor devices and/or one or more other interconnect substrates, for example.

The support substrate 20 used in making the interconnect substrate 3 according to the third embodiment may have a detachable copper foil formed on the first surface thereof to allow the plating layer 252 to be formed on the copper foil before forming the insulating layer 10, for example.

The surface of the plating layer 252 (i.e., the surface connected to the semiconductor device 30) may be recessed from the second surface 12.

### Fourth Embodiment

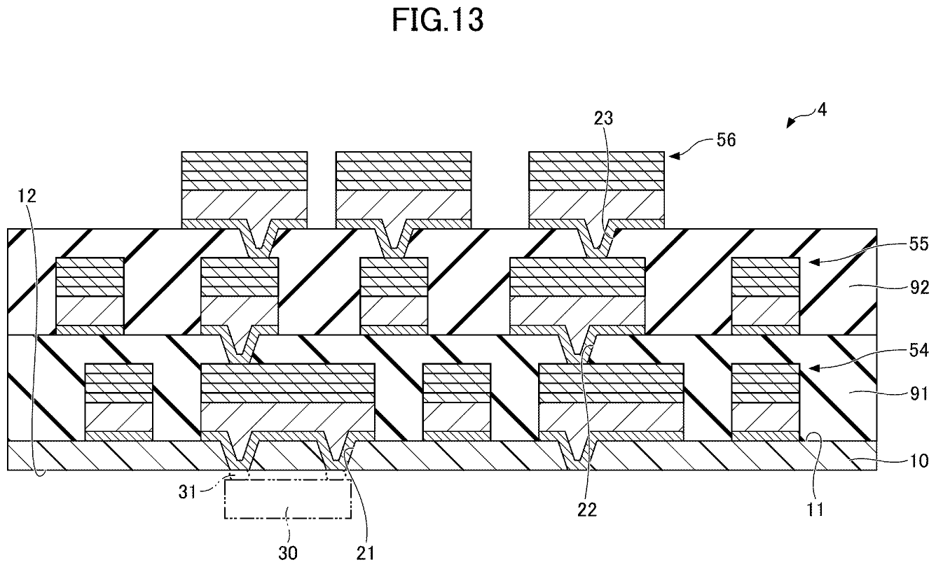

In the following, a fourth embodiment will be described. FIG. 13 is a cross-sectional view of an interconnect substrate according to the fourth embodiment.

As illustrated in FIG. 13, an interconnect substrate 4 according to the fourth embodiment has an insulating layer 91 formed on the insulating layer 10. The insulating layer 91 has via holes 22 in contact with the interconnect layer 54. An interconnect layer 55 is formed on the insulating layer 91 and coupled to the interconnect layer 54 through via conductors inside the via holes 22. Further, an insulating layer 92 is formed on the insulating layer 91. The insulating layer 92 has via holes 23 in contact with the interconnect layer 55. An interconnect layer 56 is formed on the insulating layer 92 and coupled to the interconnect layer 55 through via conductors inside the via holes 23. Like the interconnect layer 54, the interconnect layers 55 and 56 each have a seed layer, a plating layer, and a conductive layer.

The remaining configurations are substantially the same as the configurations of the first embodiment. As is described above, the fourth embodiment is provided with a multilayer interconnects.

The fourth embodiment brings about substantially the same advantageous effects as those of the first embodiment.

When making the interconnect substrate 4 according to the fourth embodiment, the insulating layer 91, the interconnect layer 55, the insulating layer 92, and the interconnect layer 56 may be formed in this order before the interconnect substrate 1 is detached from the support substrate 20 in the first embodiment, for example, and the interconnect substrate 4 may be detached from the support substrate after the interconnect layer 56 is formed. The interconnect layers 55 and 56 are formed similarly to the manner in which the interconnect layer 54 is formed.

The interconnect substrates of the present disclosures may have a core, or may not have a core.

According to at least one embodiment of the present disclosures, an interconnect substrate can conduct an increased amount of current.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

One aspect of the subject-matter described herein is set out non-exclusively in the following numbered clauses.

[Clause 1] A method of making an interconnect substrate, the method comprising:

forming a plating layer on a surface of an insulating layer;

forming, on the plating layer, an electrically conductive layer made of a sintered body comprised of an electrically conductive material.

[Clause 2] The method as recited in clause 1, wherein the forming of the plating layer includes:

forming a first layer on the surface of the insulating layer by a plating method; and

etching the first layer into the plating layer.

[Clause 3] The method as recited in clause 1, wherein the forming of the electrically conductive layer includes:

disposing a photosensitive conductive material that includes electrically conductive particles to cover the plating layer; and

forming a sintered layer comprised of the electrically conductive particles on the plating layer by exposing, developing, and heating the photosensitive conductive material.

[Clause 4] The method as recited in clause 3, wherein the disposing of the photosensitive conductive material and the forming of the sintered layer are repeated one or more times.

What is claimed is:

1. An interconnect substrate, comprising:
an insulating layer; and
an interconnect layer formed on a surface of the insulating layer,
wherein the interconnect layer includes:
a plating layer; and
an electrically conductive layer made of a sintered body comprised of an electrically conductive material.

2. The interconnect substrate as claimed in claim 1, wherein pores are present in the electrically conductive layer.

3. The interconnect substrate as claimed in claim 1, wherein the electrically conductive layer is coarser than the plating layer in a case in which a plane parallel to a thickness direction of the plating layer and the electrically conductive layer is inspected under an electron microscope.

4. The interconnect substrate as claimed in claim 1, wherein the plating layer is a Cu plating layer, and the sintered body is a copper sintered body.
